(19) United States
(12) Patent Application Publication
(10) Pub. No.: US 2004/0183701 A1
(43) Pub. Date: Sep. 23, 2004

(54) Projection-type rotary encoder

(75) Inventors: Muneo Mitamura, Nagano-ken (JP); Yoshinori Ito, Nagano-ken (JP); Sadaharu Kanamori, Nagano-ken (JP)

Correspondence Address: BURNS DOANE SWECKER & MATHIS L L P, POST OFFICE BOX 1404, ALEXANDRIA, VA, 22313-1404, US

(73) Assignee: Harmonic Drive Systems Inc.

(21) Appl. No.: 10/790,785

(22) Filed: Mar. 3, 2004

(30) Foreign Application Priority Data
Mar. 6, 2003 (JP) JP2003-059983

(51) Int. Cl. H03M 1/22; G01D 5/34

(52) U.S. Cl. 341/13; 250/231.13

(57) ABSTRACT

A projection-type rotary encoder is provided which has a light source, an object grating plate in which a substantially fan-shaped object grating for transmitting light is arranged at constant angular intervals in the circumferential direction, a rotary scale plate in which a substantially fan-shaped scale grating for transmitting light is arranged at constant angular intervals in the circumferential direction, and a photodiode grating plate in which a substantially fan-shaped photodiode photosensitive surface grating is arranged at constant angular intervals in the circumferential direction. A scale grating 32A is formed in the rotary scale plate with a shape and size that correspond to a light image of the object grating 31A incident on the surface thereof. A photodiode photosensitive surface grating 33A is formed in the photodiode grating plate with a shape and size that correspond to a light image of the scale grating 32A incident on the surface thereof.

### BACKGROUND OF THE INVENTION

1. Field of the Invention

The present invention relates to a projection-type rotary encoder based on a triple grating concept, and more particularly to a projection-type rotary encoder capable of preventing decrease of detection signal output and S/N ratio thereof by appropriately configuring the shape of the gratings.

2. Description of the Related Art

Conventional optical encoders include parallel-slit encoders and projection-type encoders based on a triple grating concept. In a parallel-slit encoder such as, for example, a transmitting encoder, a light source 1, a main scale plate 2, and a photodiode grating plate 3 are arranged in this order, as shown in FIG. 1; the luminous energy passing through a scale grating 2a of the main scale 2 plate and photosensitive surface grating 3a of the photodiode grating plate 3 varies in accordance with the relative displacement of the main scale plate 2 and photodiode grating plate 3; and an approximately sinusoidal electrical signal is output from the photodiodes formed on the photodiode grating plate 3. When a grating pitch is narrowed in order to increase resolution, an interval g between the main scale plate 2 and photodiode grating plate 3 must be narrowed because the light ceases to propagate rectilinearly due to diffraction.

In contrast, the projection-type encoder uses diffraction and interference with incoherent light, rather than coherent light such as a laser. Because of this, high resolution can be achieved without a need for high precision in a construction of the optical elements and optical system. A projection-type encoder, for example, a transmitting encoder, is configured with a light source 4, an object grating plate 5, a main scale plate 6, and a photodiode grating plate 7 arranged in this order as shown in FIG. 2, and is set so that the distance between the object grating plate 5 and the main scale plate 6 is equal to a distance between the main scale plate 6 and photodiode grating plate 7. A characteristic of this projection-type encoder is that even if an interval g between the object grating plate 5 and the main scale plate 6 becomes large, a pitch of a light image passing through an object grating 5a formed in the object grating plate 5 and a main scale 6a formed on the main scale plate 6 will remain unchanged.

Specifically, in the case of the parallel-slit system, whether a transmission or reflection type, when the gap g between the gratings increases, the image of the light that has passed through the main scale plate 2 spreads, and the pitch of the image reflected on the photodiode grating plate 3 increases, so the pitch of the image reflected on the photosensitive surface grating 3a of the photodiode grating plate 3 no longer agrees with the pitch of the grating 2a of the main scale plate 2. With the projection-type encoder, in cases of both transmission and reflection types, the pitch of the image reflected on a photosensitive surface grating 7a of the photodiode grating plate 7 is equal to the pitch of the object grating 5a and main scale 6a, even when the gap increases.

On the other hand, optical encoders include linear encoders for detecting a distance or speed of linear travel of a moving object, and rotary encoders for detecting an angle and position of rotation or rotational speed of a moving object. FIG. 3 depicts a structure of a conventionally known parallel-slit transmitting rotary encoder. Light emitted by a light source 11 such as an LED passes through a main scale plate 13 coaxially fixed on an axle 12 and through an index grating plate 14 disposed facing a scale grating 13a of the scale grating plate 13, and strikes a light-receiving element 15 such as a photodiode. Because a relative superposition of the scale grating 13a and an index grating 14a changes in accordance with rotation of the scale grating 13a, thus converting the luminous energy passing through the gratings to a substantially sinusoidal waveform, the change in the angle of rotation can be known by detecting this change in the luminous energy with a light-receiving element.

In this case, as shown in FIG. 4, in both the parallel-slit and projection-type rotary optical encoder, a shape of a scale grating 21a of a main scale plate 21 is generally designed in a fan shape based on radial lines extending from a center of the main scale plate 21 when the plate has a circular profile. An index grating 22 a of an index grating plate 22 is configured by projecting the scale grating 21a in a direction perpendicular to a surface of the grating. The actual index grating is disposed so that four groups of grating elements are offset by ¼ of a pitch in order to detect A and B phase signals differentially, but only one of those groups is shown in the schematic view of FIG. 4.

An example of a projection-type encoder is disclosed, for example, in JP-A 2000-321097.

However, in the projection-type rotary encoder, when the gratings are formed with the same fan shape and same angular interval as in the case of the parallel slit type, the output of the detection signal declines, or there is danger of the S/N ratio declining.

More specifically, in the projection-type rotary encoder, if the light source is nearly a point light source that emits diffused light, the light image passing through the gratings expands vertically and horizontally regardless of a change in the pitch of the light image. An illustration of this is shown in FIG. 5. As depicted in FIG. 5(a), because a pitch p of the rectangular scale grating in the main scale plate is constant at every part of the grating in the case of a linear type, the light image passing through forms a rectangle of the same width, and the pitch p is uniform in each part thereof. However, in the case of a rotary encoder, the grating is in a fan shape, so the grating pitch is the largest at an external periphery, gradually narrows toward an internal periphery, and is the narrowest at the internal periphery.

In the projection-type encoder, the pitches of light images 31, 32, and 33 remain equal all the way until the light emitted by the light source passes through the object grating plate and main scale plate and reaches the photodiode grating, as depicted in FIG. 5(b). Also, because the grating is fan-shaped, the pitch is the largest at a pitch p1 at the external periphery, gradually narrows toward the center, and is the narrowest at a pitch p2 at the internal periphery. As a result, a radius of the light image 31 passing through the object grating is smaller than the radius of the light image 32 passing through the main scale grating, and a radius of the light image 33 formed on the photodiode grating is larger than a radius of the light image 32 passing through the main scale grating.

In a conventional projection-type rotary encoder, the gratings have the same fan shape and are arranged at the same angular intervals without any consideration for the points described above. Because of this, a portion of the light image transmitted by the object grating is lost when the image passes through the main scale grating even when the object grating and main scale grating are at a rotational angle that ensures a complete superposition, giving rise to a condition in which a portion of the light image passing through the main scale grating is not picked up by the photodiode grating. As a result, because the luminous energy received by the photodiode is reduced, the output of the detection signal is reduced, and the S/N ratio declines.

The same phenomenon occurs in the projection-type reflecting rotary encoder depicted in FIG. 6. Specifically, light from a light source 41 passes through an object grating 42a formed in a center of a grating plate 42, reflects from the scale grating 43a of a scale grating plate 43, and focuses on a photodiode photosensitive surface grating 44a formed above and below the object grating 42a in the grating plate 42. Consequently, when viewed from a center of the scale grating 43, the light is transmitted in a radial direction from the center toward an external periphery or from the external periphery toward the center. Because of this, reduced detection signal and S/N ratio occur due to light leakage when the object grating 42a, scale grating 43a, and photodiode grating 44a are each formed in the same fan shape with the same angular interval.

FIG. 7 depicts a light image formed on the scale grating plate 43 and a light image formed on the photodiode photosensitive surface grating 44a when the object grating 42a is in a fan shape. In this figure, light emitted from the light source 41 passes through the object grating 42a, reflects from the scale grating 43a, and focuses on the photodiode grating 44a. At this time, light through points b1 and b2 on the object grating 42a strikes points a1′ and a2′. In the same manner, light through points c1 and c2 strikes points b1′ and b2′, light from points d1 and d2 strikes points e1′ and e2′, and light from points e1 and e2 strikes points f1′ and f2′. As is therefore apparent, when the object grating 42a is in a fan shape, the image formed on the photodiode grating plate 44 is in a shape that encompasses points a1′, b1′, b2′, a2′, e1′, f1′, f2′, and e2′, rather than in a fan shape that extends from the center of the scale grating 43a in a radial pattern. This results in a tendency towards reduced signal and S/N ratio. Also, in the figure, the light source is depicted by light that diverges at an emission angle, but the focusing state is depicted using collimated light to simplify the description.

In view of the foregoing, it is an object of the present invention to propose a projection-type rotary encoder that is made capable of preventing or minimizing reduction of detection signal output and S/N ratio by appropriately configuring the shape of the gratings.

### SUMMARY OF THE INVENTION

The present invention is directed to a projection-type rotary encoder having a light source, an object grating plate in which a substantially fan-shaped object grating for transmitting light is arranged at constant angular intervals in a circumferential direction, a main scale plate in which a substantially fan-shaped scale grating for transmitting light is arranged at constant angular intervals in a circumferential direction, and a photodiode grating plate in which a substantially fan-shaped photodiode photosensitive surface grating is arranged at constant angular intervals in a circumferential direction, whereby light emitted from the light source passes through the object grating and main scale plate and is received by the photodiode photosensitive surface grating; wherein

the main scale plate has the scale grating formed with a shape and size that correspond to a light image of the object grating incident on a surface thereof; and

the photodiode grating plate has the photodiode photosensitive surface grating formed with a shape and size that correspond to a light image of the scale grating incident on a surface thereof.

The shape and location of the respective gratings may be defined as follows. A single radial line is drawn through a center of the main scale plate. An external peripheral side of the scale grating is set to have the same width as that of an external peripheral side of the object grating, and is positioned at a location where the external peripheral side of the object grating is moved outwardly along the radial line in parallel fashion by a first distance. Likewise, an external peripheral side of the photodiode photosensitive surface grating is set to have the same width as that of the external peripheral side of the object grating, and is positioned at a location where the external peripheral side of the object grating is moved outwardly along the radial line in parallel fashion by a distance twice the first distance.

On the other hand, an internal peripheral side of the scale grating is set to have the same width as that of an internal peripheral side of the object grating, and is positioned at a location where the internal peripheral side of the object grating is moved inwardly along the radial direction in parallel fashion by the first distance. An internal peripheral side of the photodiode photosensitive surface grating is set to have the same width as that of the internal peripheral side of the object grating, and is positioned at a location where the internal peripheral side of the object grating is moved inwardly along the radial direction in parallel fashion by a distance twice the first distance.

Then, both ends of the external peripheral side of the scale grating are connected with corresponding ends of the internal peripheral side thereof by straight lines, so that the desired scale grating is obtained. Likewise, both ends of the external peripheral side of the photodiode photosensitive surface grating are connected with corresponding ends of the internal peripheral side thereof by straight lines, so that the desired photodiode photosensitive surface grating is obtained.

The present invention can also be applied to a projection-type reflecting rotary encoder. According to the present invention, there is provided a projection-type reflecting rotary encoder having a light source, a main scale plate in which a scale grating consisting of a substantially fan-shaped reflecting grating for reflecting light is arranged at constant angular intervals in a circumferential direction, and a grating plate disposed between the light source and the main scale plate; and also having, in the part of the grating plate that faces the scale grating, wherein

a substantially fan-shaped object grating for transmitting light is formed in part of the grating plate where the scale grating is faced, and is arranged at constant angular intervals in a circumferential direction, and

a substantially fan-shaped photodiode photosensitive surface grating is formed on a radially outer position of the object grating and/or on a radially inner position thereof, and is arranged at constant angular intervals in a circumferential, and wherein

the scale grating of the main scale plate is formed to have a shape and size that correspond to a light image of the object grating incident on the surface thereof, and

the photodiode photosensitive surface grating of the grating plate is formed to have a shape and size that correspond to a reflected light image of the scale grating incident on the surface thereof.

The shape and location of the gratings can be defined in the following manner in this case as well. A single radial line is first drawn through a center of the main scale plate. An external peripheral side of the scale grating is set to have the same width as that of an external peripheral side of the object grating, and is positioned at a location where the external peripheral side of the object grating is moved outwardly along the radial line in parallel fashion by a first distance. Likewise, an external peripheral side of the photodiode photosensitive surface grating is set to have the same width as that of the external peripheral side of the object grating, and is positioned at a location where the external peripheral side of the object grating is moved outwardly along the radial line in parallel fashion by a distance twice the first distance.

On the other hand, an internal peripheral side of the scale grating is set to have the same width as that of an internal peripheral side of the object grating, and is positioned at a location where the internal peripheral side of the object grating is moved inwardly along the radial direction in parallel fashion by the first distance. An internal peripheral side of the photodiode photosensitive surface grating is set to have the same width as that of the internal peripheral side of the object grating, and is positioned at a location where the internal peripheral side of the object grating is moved inwardly along the radial direction in parallel fashion by a distance twice the first distance.

Then, both ends of the external peripheral side of the scale grating are connected with corresponding ends of the internal peripheral side thereof by straight lines, so that the desired scale grating is obtained. Likewise, both ends of the external peripheral side of the photodiode photosensitive surface grating are connected with corresponding ends of the internal peripheral side thereof by straight lines, so that the desired photodiode photosensitive surface grating is obtained.

### BRIEF DESCRIPTION OF THE DRAWINGS

FIG. 1 is a diagram depicting a conventional parallel-slit optical encoder;

FIG. 2 is a diagram depicting a conventional projection-type optical encoder;

FIG. 3 is a diagram depicting a conventional parallel-slit rotary encoder;

FIG. 4 is a diagram depicting the shape of gratings formed in a rotary encoder;

FIG. 5(a) is a diagram depicting a light image in a projection-type linear encoder;

FIG. 5(b) is a diagram depicting a light image in a projection-type rotary encoder;

FIG. 6 is a diagram depicting a projection-type reflecting rotary encoder;

FIG. 7 is a diagram depicting the shape of a light image received by a photodiode in the projection-type rotary encoder in FIG. 6;

FIG. 8 is a diagram depicting the shape of the gratings in a projection-type reflecting rotary encoder to which the present invention is applied;

FIG. 9 is a diagram depicting the procedure for defining the shape of the gratings in the projection-type rotary encoder in FIG. 8;

FIG. 10 is a diagram depicting the procedure for defining the shape of the gratings in the projection-type rotary encoder in FIG. 8; and

FIG. 11 is a diagram depicting the shape of the gratings in a projection-type rotary encoder when the light source is a collimated light source.

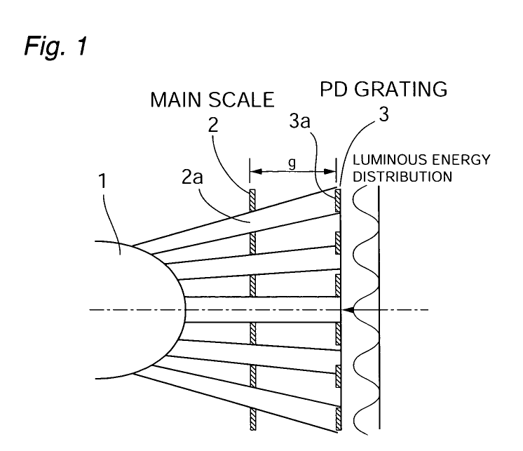

### DESCRIPTION OF THE PREFERRED EMBODIMENTS

Embodiments of a projection-type rotary encoder according to the present invention will be described with reference to the figures.

(Projection-Type Transmitting Rotary Encoder)

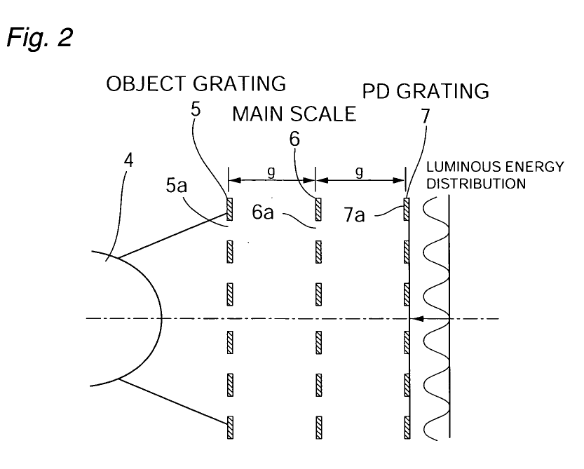

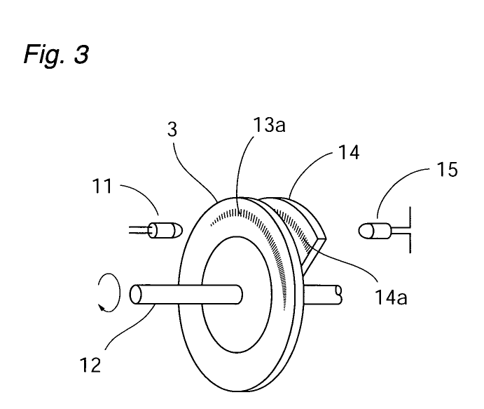

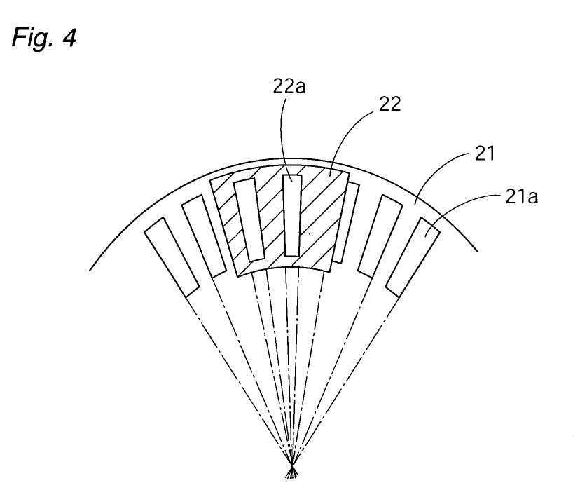

The basic structure of a projection-type transmitting rotary encoder of the present embodiment is the same as that of the conventional projection-type transmitting rotary encoder of FIG. 2. The characteristic features of the present embodiment reside in the shape and relative position of an object grating, scale grating, and photodiode photosensitive surface grating. Thus, explanation of the basic structure of the projection-type rotary encoder of this embodiment is omitted and only the characteristic features thereof will be explained hereinafter.

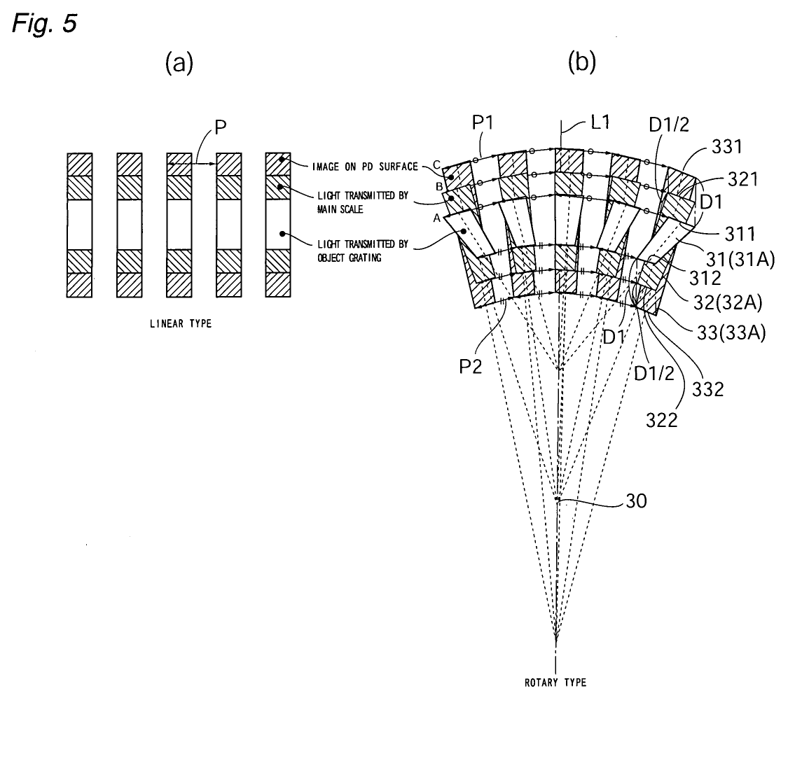

In the present embodiment, the shape and placement of the gratings are set as depicted in FIG. 5(b). Firstly, a fan-shaped scale grating 32A is formed in the circular disk-shaped main scale plate 6 at prescribed angular intervals, based on radial lines drawn from a center 30 of the main scale plate 6.

A single radial line L1 among the radial lines is selected. An external peripheral side 321 of the scale grating 32A is moved outwardly along the selected radial line L1 in parallel fashion by a prescribed first distance D1/2, to thereby obtain a position where an external peripheral side 331 of a photosensitive surface grating 33A of the photodiode grating plate 7 is placed. An internal peripheral side 322 of the scale grating 32A is moved inwardly along the selected line L1 in parallel fashion by the same distance D1/2, and a position is obtained where an internal peripheral side 332 of the photosensitive surface grating 33A is placed. Both ends of the external peripheral side 331 are connected with corresponding both ends of the internal peripheral side 332 by straight lines, so that the desired photosensitive surface grating 33A is defined.

In the same manner, the external peripheral side 321 of the scale grating 32A is moved inwardly along the radial line L1 in parallel fashion by the same distance of D1/2, and a position is obtained where an external peripheral side 311 of an object grating 31A of the object grating plate 5 is placed. Also, the internal peripheral side 322 of the scale grating 32A is moved inwardly along the radial line L1 in parallel fashion by the same distance D1/2, and a position is obtained where an internal peripheral side 312 of the object grating 32A is placed. Both ends of the external peripheral side 311 are connected with corresponding both ends of the internal peripheral side 312 by straight lines, so that the desired object grating 31A is defined.

In the projection-type rotary encoder which has the scale grating 32A, photodiode photosensitive surface grating 33A, and object grating 31A formed in this manner, gratings with a shape corresponding to a light image obtained through each of the gratings are formed in corresponding positions. Therefore, the luminous energy received by the photodiodes does not decrease, making it possible to prevent or suppress an output drop of the detection signal or a decrease of S/N ratio thereof

(Projection-Type Reflecting Rotary Encoder)

An embodiment of a projection-type reflecting rotary encoder according to the present invention will be described.

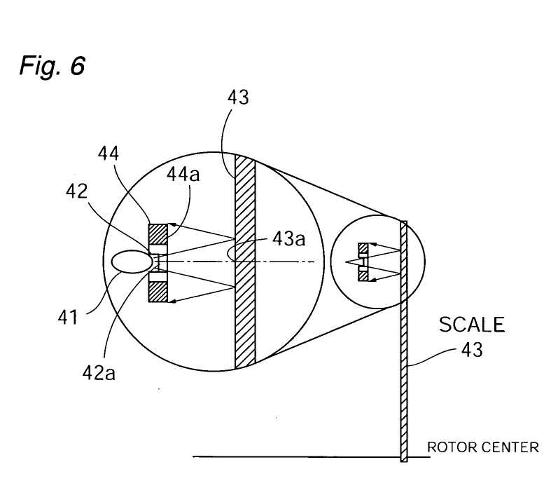

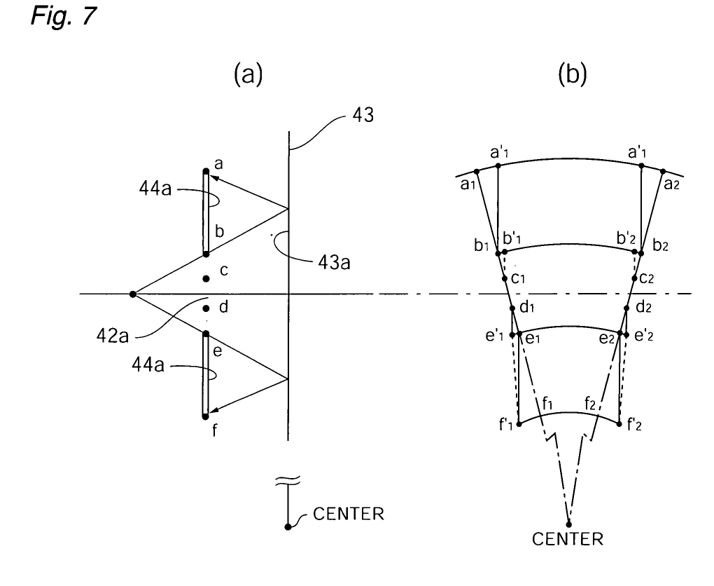

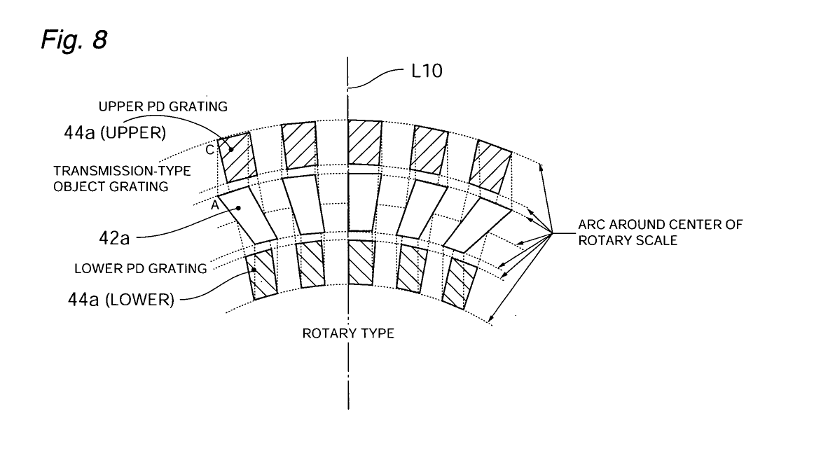

The overall structure of the projection-type reflecting rotary encoder is the same as the conventional structure depicted in FIG. 6, but an object grating 42a and upper and lower photodiode photosensitive surface gratings 44a (upper) and 44a (lower) are formed as depicted in FIG. 8.

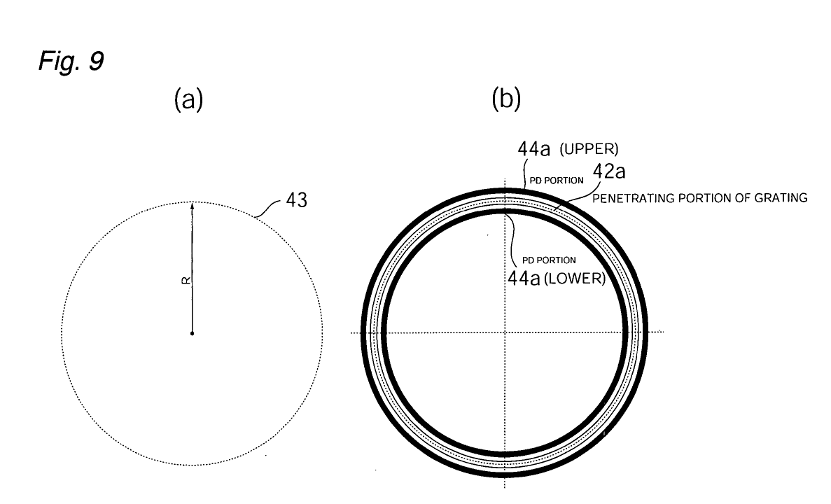

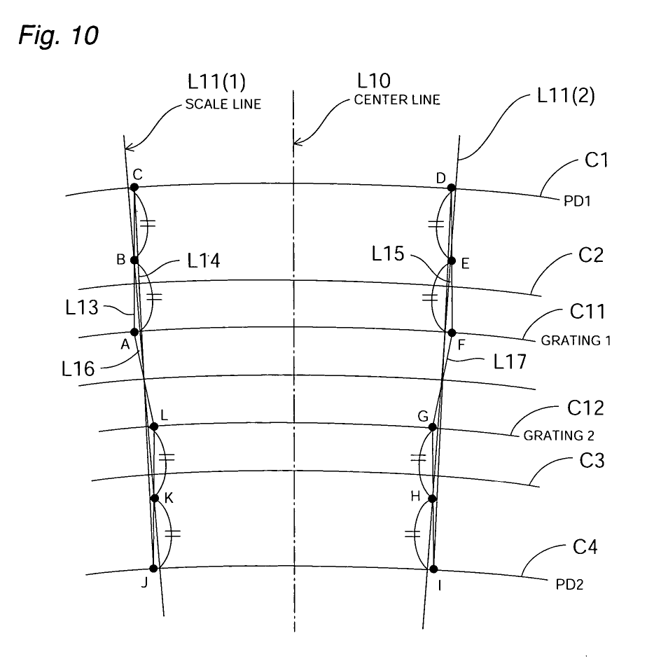

An example of a method for designing the gratings will be described with reference to FIGS. 9 and 10. A radius R of the main scale plate 43 is first defined (FIG. 9(a)). The length and width of the photodiode photosensitive surface gratings 44a (upper) and 44a (lower), and the length and width of the object grating 42a are each then defined (FIG. 9(b)). The circles C1 through C4 in FIG. 10 define the external and internal peripheral photosensitive surface gratings 44a (upper) and 44a (lower), and the circles C11 and C12 define the object grating 42a.

Scale lines are then drawn at constant angular intervals radially from the center of the main scale plate 43 to match the width of the scale grating 43a to be formed in the main scale plate 43, as depicted in FIG. 10, and a centerline L10 (radial line) is drawn for a pair of adjacent scale lines L11(1) and L11(2).

A midpoint B is then placed on the scale line L11(1) between the circumscribed circle C1 of the object grating 42a and the circumscribed circle C11 of the upper photodiode photosensitive surface grating 44a (upper).

A line segment L13 parallel to the centerline L10 is drawn from the midpoint B, the intersection thereof with the circumscribed circle C1 of the photosensitive surface grating is designated C, and the intersection thereof with the circumscribed circle C11 of the object grating is designated A. In the same manner, parallel lines are drawn from midpoints E, K, and H, and points D, F, L, J, G, and I are defined.

A line segment L14 is then drawn from point C to point J. A line segment L15 is drawn in the same manner from point D to point I. A line segment L16 is also drawn from point A to point L, and a line segment L17 is drawn from point F to point G. In this manner, the shape of the object grating 42a is defined by points A, F, G, and L, the shape of the scale grating 43a is defined by points B, E, F, G, H, K, L, and A; the shape of the photosensitive surface grating 44a (upper) on the external peripheral side is defined by points C, D, F, and A; and the shape of the photosensitive surface grating 44a (lower) on the internal peripheral side is defined by points G, I, J and L.

The required numbers of elements of the object grating 42a and upper and lower photosensitive surface gratings 44a (upper) and 44a (lower) are formed in the same manner on the left and right sides of the centerline L10. As a result, a grating shape such as is depicted in FIG. 8 is obtained.

In the projection-type reflecting rotary encoder pertaining to the present embodiment as well, gratings with a shape that corresponds to the light image obtained through each grating are formed in corresponding positions, making it possible to prevent any loss in the luminous energy received by the photodiodes. Reduced detection signal output and reduced S/N ratio can thus be prevented or minimized.

(Other Embodiments)

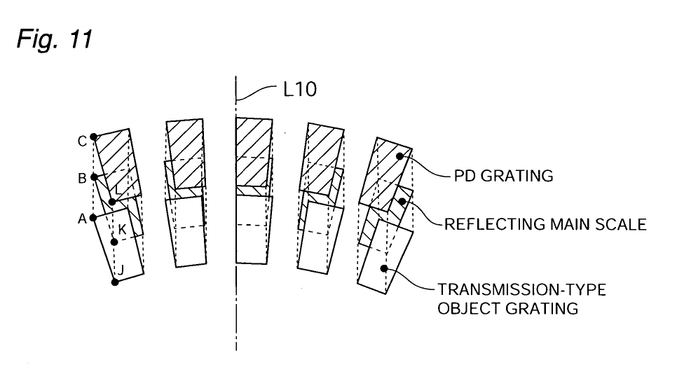

When an object that emits collimated light is used as the light source in a projection-type reflecting rotary encoder, the shapes of the object grating, scale grating and photodiode photosensitive surface grating are in agreement with each other, so the gratings may be formed by shifting the same fan-shaped outline in parallel fashion towards the external periphery side and internal periphery side along a single centerline L10 through the center of the main scale plate, as depicted in FIG. 11.

Also, in the above embodiments, the object grating and photosensitive surface grating were defined based on the fan-shaped scale grating formed in the main scale plate. Instead of this, the object grating or photosensitive surface grating may be defined first, and the rest of the gratings may be formed accordingly.

Furthermore, instead of shaping the scale grating as depicted in FIG. 10, it is possible to approximate the grating with a simpler fan configuration that includes this shape.

As described above, in the projection-type rotary encoder of the present invention, an object grating, scale grating, and photodiode photosensitive surface grating are formed such that their shapes correspond to actually formed light images at positions in which these images are actually formed.

Consequently, because loss of luminous energy received by the photodiodes can be prevented or minimized, reduced detection signal output and reduced S/N ratio can also be prevented or minimized in contrast with a case in which gratings of the same fan shape are formed in corresponding positions on each plates in the same manner as in a parallel-slit arrangement.

What is claimed is:

1. A projection-type rotary encoder having a light source, an object grating plate in which a substantially fan-shaped object grating for transmitting light is arranged at constant angular intervals in a circumferential direction, a main scale plate in which a substantially fan-shaped scale grating for transmitting light is arranged at constant angular intervals in a circumferential direction, and a photodiode grating plate in which a substantially fan-shaped photodiode photosensitive surface grating is arranged at constant angular intervals in a circumferential direction, whereby light emitted from the light source passes through the object grating and main scale plate and is received by the photodiode photosensitive surface grating; wherein
the main scale plate has the scale grating formed with a shape and size that correspond to a light image of the object grating incident on a surface thereof; and
the photodiode grating plate has the photodiode photosensitive surface grating formed with a shape and size that correspond to a light image of the scale grating incident on a surface thereof.

2. The projection-type rotary encoder according to claim 1, wherein
an external peripheral side of the scale grating is set to have the same width as that of an external peripheral side of the object grating, and is positioned at a location where the external peripheral side of the object grating is moved outwardly along a radial line in parallel fashion by a first distance, the radial line being passing through a center of the main scale plate,
an external peripheral side of the photodiode photosensitive surface grating is set to have the same width as that of the external peripheral side of the object grating, and is positioned at a location where the external peripheral side of the object grating is moved outwardly along the radial line in parallel fashion by a distance twice the first distance,
an internal peripheral side of the scale grating is set to have the same width as that of an internal peripheral side of the object grating, and is positioned at a location where the internal peripheral side of the object grating is moved inwardly along the radial direction in parallel fashion by the first distance, and
an internal peripheral side of the photodiode photosensitive surface grating is set to have the same width as that of the internal peripheral side of the object grating, and is positioned at a location where the internal peripheral side of the object grating is moved inwardly along the radial direction in parallel fashion by a distance twice the first distance.

3. A projection-type reflecting rotary encoder having a light source, a main scale plate in which a scale grating consisting of a substantially fan-shaped reflecting grating for reflecting light is arranged at constant angular intervals in a circumferential direction, and a grating plate disposed between the light source and the main scale plate; and also having, in the part of the grating plate that faces the scale grating, wherein
a substantially fan-shaped object grating for transmitting light is formed in part of the grating plate where the scale grating is faced, and is arranged at constant angular intervals in a circumferential direction,
a substantially fan-shaped photodiode photosensitive surface grating is formed on a radially outer position of the object grating and/or on a radially inner position thereof, and is arranged at constant angular intervals in a circumferential,
the scale grating of the main scale plate is formed to have a shape and size that correspond to a light image of the object grating incident on the surface thereof, and the photodiode photosensitive surface grating of the grating plate is formed to have a shape and size that correspond to a reflected light image of the scale grating incident on the surface thereof.

4. The projection-type rotary encoder according to claim 3, wherein
an external peripheral side of the scale grating is set to have the same width as that of an external peripheral side of the object grating, and is positioned at a location where the external peripheral side of the object grating is moved outwardly along a radial line in parallel fashion by a first distance, the radial line passing through a center of the main scale plate,
an external peripheral side of the photodiode photosensitive surface grating is set to have the same width as that of the external peripheral side of the object grating, and is positioned at a location where the external peripheral side of the object grating is moved outwardly along the radial line in parallel fashion by a distance twice the first distance,
an internal peripheral side of the scale grating is set to have the same width as that of an internal peripheral side of the object grating, and is positioned at a location where the internal peripheral side of the object grating is moved inwardly along the radial direction in parallel fashion by the first distance, and
an internal peripheral side of the photodiode photosensitive surface grating is set to have the same width as that of the internal peripheral side of the object grating, and is positioned at a location where the internal peripheral side of the object grating is moved inwardly along the radial direction in parallel fashion by a distance twice the first distance.
